(19) United States
(12) Patent Application Publication
(10) Pub. No.: US 2025/0351362 A1
(43) Pub. Date: Nov. 13, 2025

(54) CHANNEL LINER FOR SELECT GATE THRESHOLD VOLTAGE TUNING

(71) Applicant: Micron Technology, Inc., Boise, ID (US)

(72) Inventors: Marc Aoulaiche, Boise, ID (US); Andrew Bicksler, Nampa, ID (US); Carmine Miccoli, Boise, ID (US); James Cordeaux Brighten, Boise, ID (US); Srinath Venkatesan, Boise, ID (US); Valay Dineshbhai Shah, Kuna, ID (US)

(21) Appl. No.: 19/188,699

(22) Filed: Apr. 24, 2025

Related U.S. Application Data
(60) Provisional application No. 63/644,955, filed on May 9, 2024.

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A variety of applications can include memory devices having strings of memory cells, where a string of memory cells is coupled to a stack of drain-side select gate (SGD) transistors. The threshold voltages of the SGD transistors can be tuned to a sequence of threshold voltages by a high-k dielectric liner adjacent to and contacting selected one or more SGD transistors of the stack. Additional devices, systems, and methods are discussed.

### PRIORITY APPLICATION

This application claims the benefit of priority to U.S. Provisional Application Ser. No. 63/644,955, filed May 9, 2024, which is incorporated herein by reference in its entirety.

### FIELD OF THE DISCLOSURE

Embodiments of the disclosure relate generally to memory devices, and more specifically, to designs of components of the memory devices.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others.

Flash memory is utilized as non-volatile memory for a wide range of electronic applications. Flash memory devices typically include one or more groups of one-transistor, floating gate or charge trap memory cells that allow for high memory densities, high reliability, and low power consumption. Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a data line.

Using 3D architectures for memory devices, such as NAND memory devices, can provide increased capacity over planar structures. The memory arrays for 3D structures can include memory cells stacked vertically as strings of memory cells. In selecting one or more strings for access to given memory cells, gating structures can be located at the top and bottom of these strings with memory cells storing data therebetween. The gating structures can include one or more select gate transistors with its drain coupled to a data line, such as a bitline, at one end of a string and one or more select gate transistors with its source coupled to a source line at the other end of the string. A drain-side select gate transistor with its drain coupled to a data line of a string of memory cells is herein referred to as a SGD transistor and a source-side select transistor with its source coupled to a source line for the string of memory cells is herein referred to as a SGS transistor. Design improvements of gating structures, such as SGD transistors or SGS transistors, can enhance control of operation of the stings of memory cells of a memory device.

### BRIEF DESCRIPTION OF THE DRAWINGS

The drawings, which are not necessarily drawn to scale, illustrate generally, by way of example, but not by way of limitation, various embodiments discussed in the present document.

FIGS. 1-8 illustrate examples of memory devices having multiple select gate transistors arranged vertically in a stack to a string of memory cells, where a dielectric liner is adjacent and contacting the transistor channel structure of one or more of the multiple select gate transistors, according to various embodiments.

FIG. 9 is a flow diagram of features of an example method of forming a memory device having one or more select gate transistors in which threshold voltage is tuned, according to various embodiments.

FIG. 10 is a flow diagram of features of an example method of forming a memory device having multiple select gate transistors that can be formed with a selected sequence of threshold voltages, according to various embodiments.

FIG. 11 illustrates a block diagram of an example machine having one or more memory devices structured with a dielectric liner implemented to tune the threshold voltages of one or more drain-side select gate transistors, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

Both NOR and NAND flash architecture semiconductor memory arrays of flash memory devices are accessed through decoders that activate specific memory cells by selecting an access line (WL) coupled to gates of specific memory cells. In a NOR architecture semiconductor memory array, once activated, the selected memory cells place their data values on data lines, causing different currents to flow depending on the state at which a particular cell is programmed. In a NAND architecture semiconductor memory array, a relatively high bias voltage is applied to a drain-side select gate (SGD) line. Access lines coupled to the gates of the unselected memory cells of each group are driven at a specified pass voltage to operate the unselected memory cells of each group as pass transistors (e.g., to pass current in a manner unrestricted by their stored data values). Current then flows in the line between the source line and the data line through each series-coupled group, restricted only by the selected memory cells of each group, placing current-encoded data values of selected memory cells on the data lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data. Flash memory cells can also represent more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC has been referred to as a memory cell that can store two bits of data per cell (e.g., one of four programmed states). MLC is used herein in its broader context, to refer to any memory cell(s) that can store more than one bit of data per cell (i.e., that can represent more than two programmed states). Herein, a memory cell that can store two bits of data per cell (e.g., one of four programmed states) is referred to as a dual-level cell (DLC). A triple-level cell (TLC) refers to a memory cell that can store three bits of data per cell (e.g., one of eight programmed states). A quad-level cell (QLC) can store four bits of data per cell, and a penta-level cell (PLC) can store five bits of data per cell.

In a string of memory cells in a 3D memory device such as a 3D NAND memory, access to the string to operate on a memory cell in the string cell can be controlled by one or more SGD transistors, which is coupled to the string of memory cells. In a stack of SGD transistor cells, an optimum Vt window and Vt configuration of SGD transistor cells should be used for good operation of the memory array and to avoid boost leakage, slow to program issues, or reliability issues. A Vt window for a transistor provides a range of values for Vt from a minimum voltage to a maximum voltage. The window can be divided into three Vt regions: a low Vt, a medium Vt, and a high Vt. A low Vt can range from the minimum value of the Vt window to a value positioned at about one-third of the window from the minimum. A medium Vt can range in about a middle one-third of the Vt window below a threshold for a minimum high Vt, where the high Vt ranges from the threshold to the largest value of the Vt window. The window can be divided three regions by a factor different from thirds or into a number of other regions different from three regions. A Vt configuration of SGD cells can be realized by a sequence of SGD transistors having a sequence of Vts such as (high Vt, high Vt, low or medium Vt, medium Vt, low Vt . . . ). Various sequences can be used depending on the application for the stack of SGD transistors. Conventional processing techniques adjust the Vt of a SGD transistor by boron implant. However, it is challenging to obtain a specified Vt and difficult to control the boron diffusion. In addition, lateral contact processing of the gates to the SGD transistor cells use high diffusion temperature to enable up-diffusion of a dopant from the source side, which is at the bottom of the vertical string of SGD transistor cells, memory cells, and SGS transistor cells. Lateral contact processing of the gates to the SGD transistor cells also uses a lower Vt for the SGS transistors, which worsens the SGD Vt issue and makes it even more challenging to achieve lower SGS Vts but higher SGD Vts.

In various embodiments, a high-k dielectric film can be used as a channel liner adjacent and contacting transistor channel structures of one or more transistors to adjust the Vts of these transistors. The channel liner can be positioned on a side of the transistor channel structures opposite the side of the transistor channel structures to which the gates of the one or more transistors are positioned. A high-k dielectric is a dielectric material having a dielectric constant greater than the dielectric constant of silicon dioxide, which is approximately 3.9. A stack of multiple transistors can include a channel structure that provides the transistor channel of each of the transistors of the multiple transistors. The multiple transistors can be structured with a dielectric fill adjacent to the channel structure. The dielectric fill can be a fill volume around which the transistors are structured. The high-k dielectric channel liner can be structured within the dielectric fill with different thicknesses to adjust the Vt of the transistors to which the channel liner is adjacent. With the high-k dielectric channel liner having the same thickness adjacent each transistor of a sequence of transistors of the multiple transistors, the high-k dielectric liner can provide a common value of Vt for the transistors of the sequence different from the values of the transistors of the multiple transistors not in the sequence. Alternatively, the high-k dielectric liner can vary in its thickness along its length contacting the sequence to provide the transistors of the sequence with different Vts and different from the transistors not in the sequence. Each transistor of the multiple transistors can be formed with substantially the same structure, but with variations such as in doping to effect a low or medium Vt for a respective transistor not adjacent a high-k dielectric liner. The transistors can be metal-oxide semiconductor field effect transistor (MOSFET) transistors, floating gate transistors, charge trap cells, or similar transistor cells. The stack of multiple transistors can be SGD transistors arranged above and coupled to a string of memory cells in a memory array of a memory device. One or more SGS transistors can be arranged below and coupled to the string of memory cells.

The high-k dielectric liner can be realized as, but is not limited to AlOₓ film within in a dielectric fill adjacent the SGD transistors. The dielectric fill can be a non-high-k material such as, but not limited to, silicon oxide. With the high-k liner adjacent a transistor channel being an AlOx film, an increase in Vt of up to a 1.5V increase has been evaluated by the inventors. Other high-k films or combinations of high-k films can be used. The high-k liner is substantially immune to diffusion allowing procedures to optimize the Vt of lower SGS transistors in a manner that is almost independent of tuning the SGD transistor to a relatively high Vt, where the SGD transistor is of the same string as the SGS transistors. The high-k liner adjacent a SGD transistor provides a mechanism for tuning the Vt of the SGD transistor that can be a different mechanism from tuning the SGS transistors. Vt tuning is the setting or adjusting of the Vt of a transistor, which can be performed during the fabrication of the transistor.

Different Vt values can be achieved for a desired specification of SGD transistors by controlling the thickness of a dielectric liner adjacent and contacting the SGD transistors. The Vt tuning provided by controlling the thickness of the dielectric liner for multiple SGD transistors makes it possible to achieve different cell Vt configurations as desired for a given specification. The stack of multiple SGD transistors can be structured with the high-k liner in a pillar that is arranged on a pillar containing a string of memory cells. The stack can include a few SGD transistor cells targeted with a sequence of Vts such as (high, low, low), (high, medium, medium), (medium, high, low), or other sequences. A high-k dielectric liner can also be used in structures in which the multiple SGD transistor cells are integrated in the same pillar as the memory cells of the array.

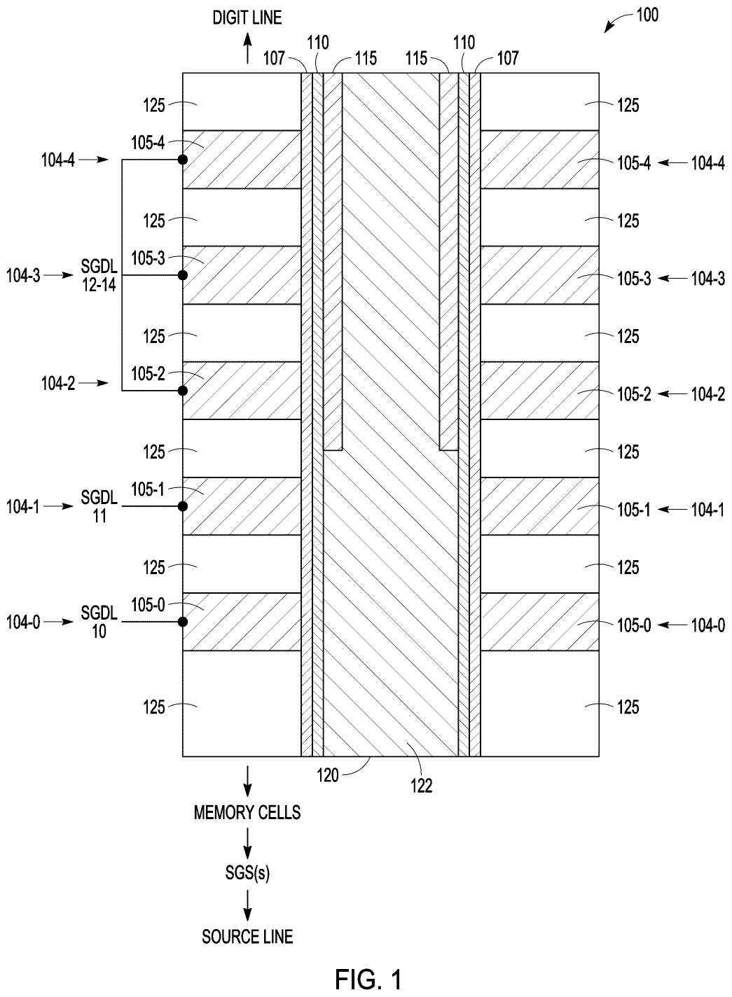

FIGS. 1-8 illustrate embodiments of example memory devices having multiple select gate transistors arranged vertically in a stack to a string of memory cells and a channel structure extending vertically in the stack, where the channel structure is arranged as a transistor channel structure of each of the multiple select gate transistors. The memory device can include a dielectric liner adjacent and contacting the transistor channel structure of one or more of the multiple select gate transistors, where the dielectric liner is structured with respect to the channel structure to provide a configuration of one or more of a high threshold voltage select gate transistor, a medium threshold voltage select gate transistor, or a low threshold voltage select gate transistor among the multiple select gate transistors. The dielectric liner can include a high-k dielectric material. The channel structure can be structured around a dielectric fill in a horizontal direction along a vertical length of the channel. The dielectric fill can contain the dielectric liner and a dielectric region below a bottommost select gate transistor of the multiple select gate transistors, where the dielectric region is a non-high-k dielectric. The non-high-k dielectric region can be, but is not limited to, silicon oxide. The dielectric fill can be a non-high-k dielectric except in the regions occupied by the dielectric liner.

FIG. 1 illustrates an arrangement 100 in a memory device having SGD transistors 104-0, 104-1, 104-2, 104-3, and 104-4 vertically positioned above and coupled to memory cells, with the memory cells arranged above one or more SGS transistors coupled to a source line of the memory device. SGD transistors 104-0, 104-1, 104-2, 104-3, and 104-4, arranged in a vertical stack, can be coupled to a digit line above SGD transistors 104-0, 104-1, 104-2, 104-3, and 104-4. A channel structure 110 can be arranged vertically in the stack of SGD transistors 104-0, 104-1, 104-2, 104-3, and 104-4 such that channel structure 110 provides a transistor channel for SGD transistors 104-0, 104-1, 104-2, 104-3, and 104-4. Isolation regions 125 separate each of SGD transistors 104-0, 104-1, 104-2, 104-3, and 104-4 from directly adjacent ones of SGD transistors 104-0, 104-1, 104-2, 104-3, and 104-4. A gate dielectric material 107 provides a gate dielectric for each of SGD transistors 104-0, 104-1, 104-2, 104-3, and 104-4. Gate dielectric material 107 can be arranged to run continuously in the vertical stack of SGD transistors 104-0, 104-1, 104-2, 104-3, and 104-4, vertically contacting the isolation regions 125. Alternatively, gate dielectric material 107 can be segmented positioned vertically between isolation regions 125. SGD transistors 104-0, 104-1, 104-2, 104-3, and 104-4 can include gates 105-0, 105-1, 105-2, 105-3, and 105-4, respectively, separated by gate dielectric material 107 from channel structure 110.

Gate 105-0 of SGD transistor 104-0 can be coupled to a SGD select line SGDL 10. Gate 105-1 of SGD transistor 104-1 can be coupled to a SGD select line SGDL 11. Gate 105-2 of SGD transistor 104-2 can be coupled to a SGD select line SGDL 12. Gate 105-3 of SGD transistor 104-3 can be coupled to a SGD select line SGDL 13. Gate 105-4 of SGD transistor 104-4 can be coupled to a SGD select line SGDL 14. SGL 12, SGL 13, and SGL 14 are coupled together to provide the same voltage to the gates of SGD transistor 104-2, SGD transistor 104-3, and SGD transistor 104-4. Alternatively, none of the gates of the SGD transistors are coupled together or a different number of gates the SGD transistors coupled together. Though FIG. 1 shows arrangement 100 having five SGD transistors, arrangement 100 can have more or fewer than five SGD transistors.

Arrangement 100 can include SGD transistors 104-0, 104-1, 104-2, 104-3, 104-4 formed around a dielectric fill 120. In the fabrication process, dielectric fill 120 can be formed after forming the SGD transistors. Dielectric fill 120 can include a dielectric liner 115 and a dielectric region 122. Dielectric liner 115 can be a high-k dielectric liner and dielectric region 122 can be a non-high-k dielectric region. Dielectric liner 115 can extend from above SGD transistor 104-4, which is a topmost select gate transistor of the multiple select gate transistors of arrangement 100, to below SGD transistor 104-2, which is a bottommost transistor in a sequence of SGD transistor 104-4, SGD transistor 104-3, and SGD transistor 104-2 arranged vertically directly from the topmost select gate transistor. Dielectric liner 115 does not contact SGD transistor 104-0 and SGD transistor 104-1 positioned below the sequence. Dielectric liner 115 has been formed having a thin thickness in the horizontal direction along the length of dielectric liner 115 to tune the Vts of SGD transistor 104-2, SGD transistor 104-3, and SGD transistor 104-4 to a different Vt than the Vts of SGD transistors 104-0 and 104-1. A thin thickness can be approximately one thirteenth of the radius of dielectric fill 120. Other thin thicknesses can be used. The selection of thin and thick thicknesses can depend on the material of dielectric liner 115. For an AlOₓ dielectric liner, thickness can be selected to be relative to 1 nm. Thick can be 1 nm and higher and thin can be below 1 nm up to a few Angstroms. Other thin and thick values can be used in the formation of dielectric liner 115, in accordance with the specification for the pillars of the memory device. Thin thickness provides a lower increase of Vt with respect to non-liner regions than thicker thicknesses with respect to non-liner regions for dielectric liner 115. The Vts of the SGD transistors can be tuned by varying the thin thickness of dielectric liner 515.

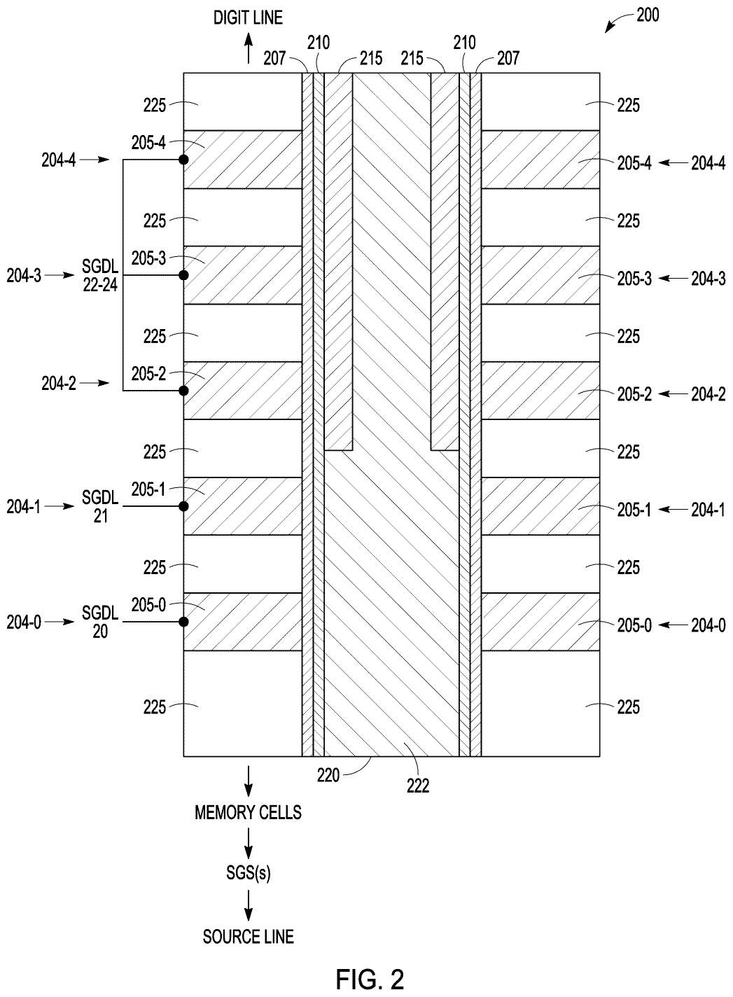

FIG. 2 illustrates an arrangement 200 in a memory device having SGD transistors 204-0, 204-1, 204-2, 204-3, and 204-4 vertically positioned above and coupled to memory cells, with the memory cells arranged above one or more SGS transistors coupled to a source line of the memory device. SGD transistors 204-0, 204-1, 204-2, 204-3, and 204-4, arranged in a vertical stack, can be coupled to a digit line above SGD transistors 204-0, 204-1, 204-2, 204-3, and 204-4. A channel structure 210 can be arranged vertically in the stack of SGD transistors 204-0, 204-1, 204-2, 204-3, and 204-4 such that channel structure 210 provides a transistor channel for SGD transistors 204-0, 204-1, 204-2, 204-3, and 204-4. Isolation regions 225 separate each of SGD transistors 204-0, 204-1, 204-2, 204-3, and 204-4 from directly adjacent ones of SGD transistors 204-0, 204-1, 204-2, 204-3, and 204-4. Channel structure 210 can be arranged to run continuously in the vertical stack of SGD transistors 204-0, 204-1, 204-2, 204-3, and 204-4. A gate dielectric material 207 provides a gate dielectric for each of SGD transistors 204-0, 204-1, 204-2, 204-3, and 204-4. Gate dielectric material 207 can be arranged to run continuously in the vertical stack of SGD transistors 204-0, 204-1, 204-2, 204-3, and 204-4, vertically contacting the isolation regions 225. Alternatively, gate dielectric material 207 can be segmented positioned vertically between isolation regions 225. SGD transistors 204-0, 204-1, 204-2, 204-3, and 204-4 can include gates 205-0, 205-1, 205-2, 205-3, and 205-4, respectively, separated by gate dielectric material 207 from channel structure 210.

Gate 205-0 of SGD transistor 204-0 can be coupled to a SGD select line SGDL 20. Gate 205-1 of SGD transistor 204-1 can be coupled to a SGD select line SGDL 21. Gate 205-2 of SGD transistor 204-2 can be coupled to a SGD select line SGDL 22. Gate 205-3 of SGD transistor 204-3 can be coupled to a SGD select line SGDL 23. Gate 205-4 of SGD transistor 204-4 can be coupled to a SGD select line SGDL 24. SGL 22, SGL 23, and SGL 24 can be coupled together to provide the same voltage to the gates of SGD transistor 204-2, SGD transistor 204-3, and SGD transistor 204-4. Alternatively, none of the gates of the SGD transistors are coupled together or a different number of gates the SGD transistors coupled together. Though FIG. 2 shows arrangement 200 having five SGD transistors, arrangement 200 can have more or fewer than five SGD transistors.

Arrangement 200 can include SGD transistors 204-0, 204-1, 204-2, 204-3, 204-4 formed around a dielectric fill 220. In the fabrication process, dielectric fill 220 can be formed after forming the SGD transistors. Dielectric fill 120 can include a dielectric liner 215 and a dielectric region 222. Dielectric liner 215 can be a high-k dielectric liner and dielectric region 222 can be a non-high-k dielectric region. Dielectric liner 215 can extend from above SGD transistor 204-4, which is a topmost select gate transistor of the multiple select gate transistors of arrangement 200, to below SGD transistor 204-2, which is a bottommost transistor in a sequence of SGD transistor 204-4, SGD transistor 204-3, and SGD transistor 204-2 arranged vertically directly from the topmost select gate transistor. Dielectric liner 215 does not contact SGD transistor 204-0 and SGD transistor 204-1 positioned below the sequence. Dielectric liner 215 has been formed having a thick thickness in the horizontal direction along the length of dielectric liner 215 to tune the Vts of SGD transistor 204-2, SGD transistor 204-3, and SGD transistor 204-4 to a different Vt than the Vts of SGD transistors 204-0 and 204-1. A thick thickness can be greater than approximately one thirteenth of the radius of dielectric fill 120 and less than one-half the radius. Other thick thickness ranges can be used. The Vts of the SGD transistors can also be tuned by varying the thick thickness of dielectric liner 515. The selection of thin and thick thicknesses can depend on the material of dielectric liner 215. For an AlOₓ dielectric liner, thickness can be selected to be relative to 1 nm. Thick can be 1 nm and higher and thin can be below 1 nm up to a few Angstroms. Other thin and thick values can be used in the formation of dielectric liner 215, in accordance with the specification for the pillars of the memory device. Thin thickness provide a lower increase of Vt with respect to non-liner regions than thicker thickness with respect to non-liner regions.

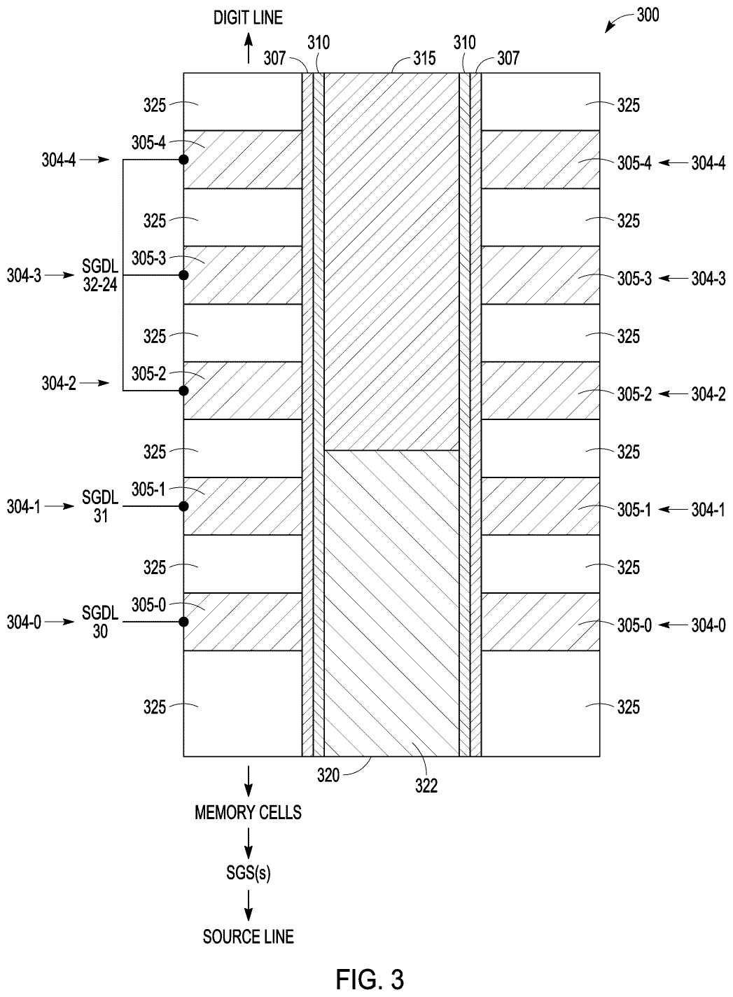

FIG. 3 illustrates an arrangement 300 in a memory device having SGD transistors 304-0, 304-1, 304-2, 304-3, and 304-4 vertically positioned above and coupled to memory cells, with the memory cells arranged above one or more SGS transistors coupled to a source line of the memory device. SGD transistors 304-0, 304-1, 304-2, 304-3, and 304-4, arranged in a vertical stack, can be coupled to a digit line above SGD transistors 304-0, 304-1, 304-2, 304-3, and 304-4. A channel structure 310 can be arranged vertically in the stack of SGD transistors 304-0, 304-1, 304-2, 304-3, and 304-4 such that channel structure 310 provides a transistor channel for SGD transistors 304-0, 304-1, 304-2, 304-3, and 304-4. Isolation regions 325 separate each of SGD transistors 304-0, 304-1, 304-2, 304-3, and 304-4 from directly adjacent ones of SGD transistors 304-0, 304-1, 304-2, 304-3, and 304-4. Channel structure 310 can be arranged to run continuously in the vertical stack of SGD transistors 304-0, 304-1, 304-2, 304-3, and 304-4. A gate dielectric material 307 provides a gate dielectric for each of SGD transistors 304-0, 304-1, 304-2, 304-3, and 304-4. Gate dielectric material 307 can be arranged to run continuously in the vertical stack of SGD transistors 304-0, 304-1, 304-2, 304-3, and 304-4, vertically contacting the isolation regions 325. Alternatively, gate dielectric material 307 can be segmented positioned vertically between isolation regions 325. SGD transistors 304-0, 304-1, 304-2, 304-3, and 304-4 can include gates 305-0, 305-1, 305-2, 305-3, and 305-4, respectively, separated by gate dielectric material 307 from channel structure 310.

Gate 305-0 of SGD transistor 304-0 can be coupled to a SGD select line SGDL 30. Gate 305-1 of SGD transistor 304-1 can be coupled to a SGD select line SGDL 31. Gate 305-2 of SGD transistor 304-2 can be coupled to a SGD select line SGDL 32. Gate 305-3 of SGD transistor 304-3 can be coupled to a SGD select line SGDL 33. Gate 305-4 of SGD transistor 304-4 can be coupled to a SGD select line SGDL 34. SGL 32, SGL 33, and SGL 34 can be coupled together to provide the same voltage to the gates of SGD transistor 304-2, SGD transistor 304-3, and SGD transistor 304-4. Alternatively, none of the gates of the SGD transistors are coupled together or a different number of gates the SGD transistors coupled together. Though FIG. 3 shows arrangement 300 having five SGD transistors, arrangement 300 can have more or fewer than five SGD transistors.

Arrangement 300 can include SGD transistors 304-0, 304-1, 304-2, 304-3, and 304-4 formed around a dielectric fill 320. In the fabrication process, dielectric fill 320 can be formed after forming the SGD transistors. Dielectric fill 320 can include a dielectric liner 315 and a dielectric region 322. Dielectric liner 315 can be a high-k dielectric liner and dielectric region 322 can be a non-high-k dielectric region. Dielectric liner 315 can extend from above SGD transistor 304-4, which is a topmost select gate transistor of the multiple select gate transistors of arrangement 300, to below SGD transistor 304-2, which is a bottommost transistor in a sequence of SGD transistor 304-4, SGD transistor 304-3, and SGD transistor 304-2 arranged vertically directly from the topmost select gate transistor. Dielectric liner 315 does not contact SGD transistor 304-0 and SGD transistor 304-1 positioned below the sequence. Dielectric liner 315 has been formed having a thick thickness in the horizontal direction along the length of dielectric liner 315 to tune the Vts of SGD transistor 304-2, SGD transistor 304-3, and SGD transistor 304-4 to a different Vt than the Vts of SGD transistors 304-0 and 304-1. The thickness of dielectric liner 315 fills dielectric fill 320 above and is positioned contacting dielectric region 322 increasing the Vts of SGD transistors 304-2, 304-3, and 304-4 to high values relative to the Vts of SGD transistors adjacent non-liner regions.

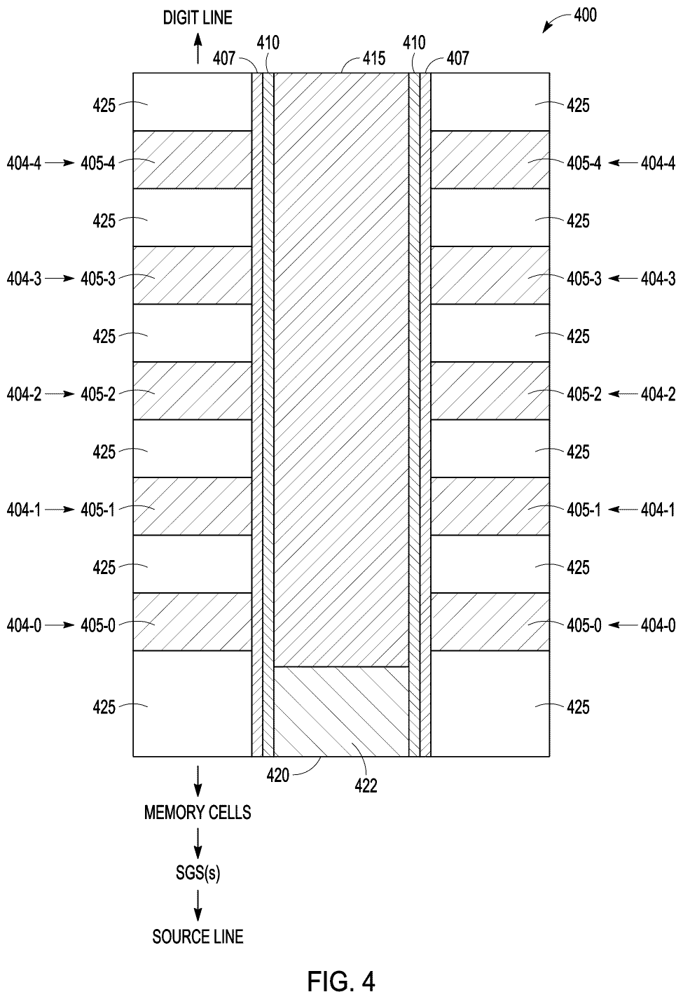

FIG. 4 illustrates an arrangement 400 in a memory device having SGD transistors 404-0, 404-1, 404-2, 404-3, and 404-4 vertically positioned above and coupled to memory cells, with the memory cells arranged above one or more SGS transistors coupled to a source line of the memory device. SGD transistors 404-0, 404-1, 404-2, 404-3, and 404-4, arranged in a vertical stack, can be coupled to a digit line above SGD transistors 404-0, 404-1, 404-2, 404-3, and 404-4. A channel structure 410 can be arranged vertically in the stack of SGD transistors 404-0, 404-1, 404-2, 404-3, and 404-4 such that channel structure 410 provides a transistor channel for SGD transistors 404-0, 404-1, 404-2, 404-3, and 404-4. Isolation regions 425 separate each of SGD transistors 404-0, 404-1, 404-2, 404-3, and 404-4 from directly adjacent ones of SGD transistors 404-0, 404-1, 404-2, 404-3, and 404-4. Channel structure 410 can be arranged to run continuously in the vertical stack of SGD transistors 404-0, 404-1, 404-2, 404-3, and 404-4. A gate dielectric material 407 provides a gate dielectric for each of SGD transistors 404-0, 404-1, 404-2, 404-3, and 404-4. Gate dielectric material 407 can be arranged to run continuously in the vertical stack of SGD transistors 404-0, 404-1, 404-2, 404-3, and 404-4, vertically contacting the isolation regions 425. Alternatively, gate dielectric material 407 can be segmented positioned vertically between isolation regions 425. SGD transistors 404-0, 404-1, 404-2, 404-3, and 404-4 can include gates 405-0, 405-1, 405-2, 405-3, and 405-4, respectively, separated by gate dielectric material 407 from channel structure 410.

Each gate of SGD transistors 404-0, 404-1, 404-2, 404-3, and 404-4 can be coupled to a SGD select line assigned to each of SGD transistors 404-0, 404-1, 404-2, 404-3, and 404-4. Selected ones of the SGD select lines can be coupled together to provide the same voltage to the gates of the corresponding selected ones of the SGD transistors. Alternatively, none of the gates of the SGD transistors are coupled together. Though FIG. 4 shows arrangement 400 having five SGD transistors, arrangement 400 can have more or fewer than five SGD transistors.

Arrangement 400 can include SGD transistors 404-0, 404-1, 404-2, 404-3, and 404-4 formed around a dielectric fill 420. In the fabrication process, dielectric fill 420 can be formed after forming the SGD transistors. Dielectric fill 420 can include a dielectric liner 415 and a dielectric region 422. Dielectric liner 415 can be a high-k dielectric liner and dielectric region 422 can be a non-high-k dielectric region. Dielectric liner 415 can extend from above SGD transistor 404-4, which is a topmost select gate transistor of the multiple select gate transistors of arrangement 400, to below SGD transistor 404-0, which is a bottommost transistor of the stack of SGD transistor 404-0, SGD transistor 404-1, SGD transistor 404-2, SGD transistor 404-3, and SGD transistor 404-4 arranged vertically. Dielectric liner 415 has been formed having a thick thickness in the horizontal direction along the length of dielectric liner 415 to tune the Vts of all the SGD transistors in the stack. The thickness of dielectric liner 415 horizontally fills dielectric fill 420 above and is positioned contacting dielectric region 422 at a position below the bottommost SGD transistor 404-0 in the stack. This provides a high Vt for all the transistors of the stack of SGD transistor 404-0, SGD transistor 404-1, SGD transistor 404-2, SGD transistor 404-3, and SGD transistor 404-4.

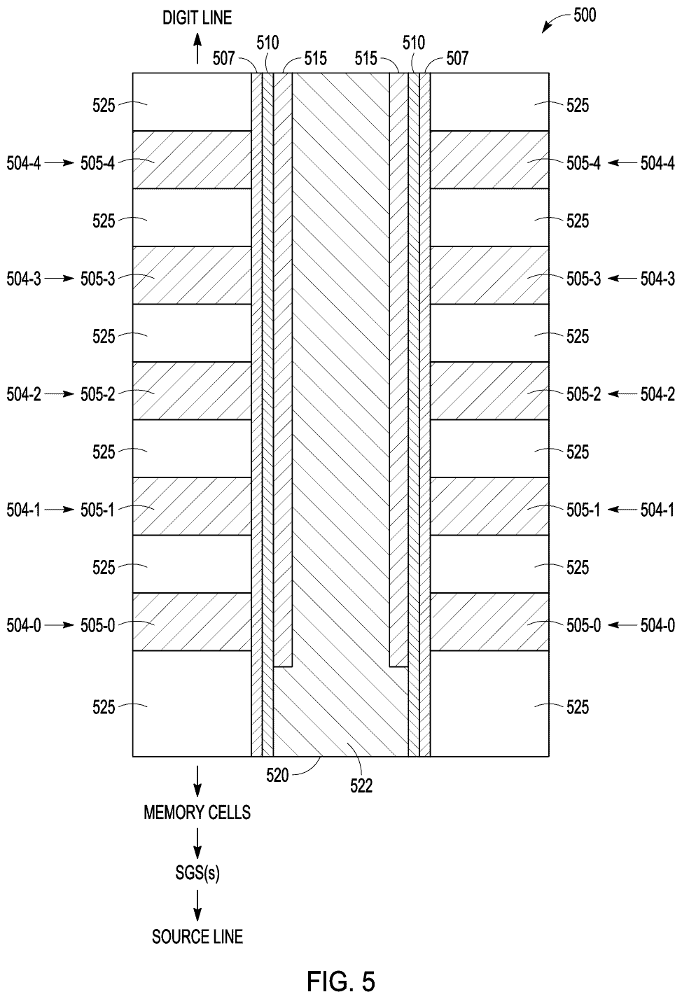

FIG. 5 illustrates an arrangement 500 in a memory device having SGD transistors 504-0, 504-1, 504-2, 504-3, and 504-4 vertically positioned above and coupled to memory cells, with the memory cells arranged above one or more SGS transistors coupled to a source line of the memory device. SGD transistors 504-0, 504-1, 504-2, 504-3, and 504-4, arranged in a vertical stack, can be coupled to a digit line above SGD transistors 504-0, 504-1, 504-2, 504-3, and 504-4. A channel structure 510 can be arranged vertically in the stack of SGD transistors 504-0, 504-1, 504-2, 504-3, and 504-4 such that channel structure 510 provides a transistor channel for SGD transistors 504-0, 504-1, 504-2, 504-3, and 504-4. Isolation regions 525 separate each of SGD transistors 504-0, 504-1, 504-2, 504-3, and 504-4 from directly adjacent ones of SGD transistors 504-0, 504-1, 504-2, 504-3, and 504-4. Channel structure 510 can be arranged to run continuously in the vertical stack of SGD transistors 504-0, 504-1, 504-2, 504-3, and 504-4. A gate dielectric material 507 provides a gate dielectric for each of SGD transistors 504-0, 504-1, 504-2, 504-3, and 504-4. Gate dielectric material 507 can be arranged to run continuously in the vertical stack of SGD transistors 504-0, 504-1, 504-2, 504-3, and 504-4, vertically contacting the isolation regions 525. Alternatively, gate dielectric material 507 can be segmented positioned vertically between isolation regions 525. SGD transistors 504-0, 504-1, 504-2, 504-3, and 504-4 can include gates 505-0, 505-1, 505-2, 505-3, and 505-4, respectively, separated by gate dielectric material 507 from channel structure 510.

Each gate of SGD transistors 504-0, 504-1, 504-2, 504-3, and 504-4 can be coupled to a SGD select line assigned to each of SGD transistors 504-0, 504-1, 504-2, 504-3, and 504-4. Selected ones of the SGD select lines can be coupled together to provide the same voltage to the gates of the corresponding selected ones of the SGD transistors. Alternatively, none of the gates of the SGD transistors are coupled together. Though FIG. 5 shows arrangement 500 having five SGD transistors, arrangement 500 can have more or fewer than five SGD transistors.

Arrangement 500 can include SGD transistors 504-0, 504-1, 504-2, 504-3, and 504-4 formed around a dielectric fill 520. In the fabrication process, dielectric fill 520 can be formed after forming the SGD transistors. Dielectric fill 520 can include a dielectric liner 515 and a dielectric region 522. Dielectric liner 515 can be a high-k dielectric liner and dielectric region 522 can be a non-high-k dielectric region. Dielectric liner 515 can extend from above SGD transistor 504-4, which is a topmost select gate transistor of the multiple select gate transistors of arrangement 500, to below SGD transistor 504-0, which is a bottommost transistor of the stack of SGD transistor 504-0, SGD transistor 504-1, SGD transistor 504-2, SGD transistor 504-3, and SGD transistor 504-4 arranged vertically. Dielectric liner 515 can be formed having a thin or a thick thickness that does not fill dielectric fill 520 in the horizontal direction. Dielectric region 522 can be formed with dielectric liner 515 above and on dielectric region 522 and with dielectric liner 515 separating the SGD transistors from dielectric region 522 along the dielectric liner 515. The Vts of all the SDG transistors is tuned by forming dielectric liner 515 with a specific thickness. The Vts of the SGD transistors can be tuned by varying the thickness of dielectric liner 515, without filling dielectric fill 520 with dielectric liner 515.

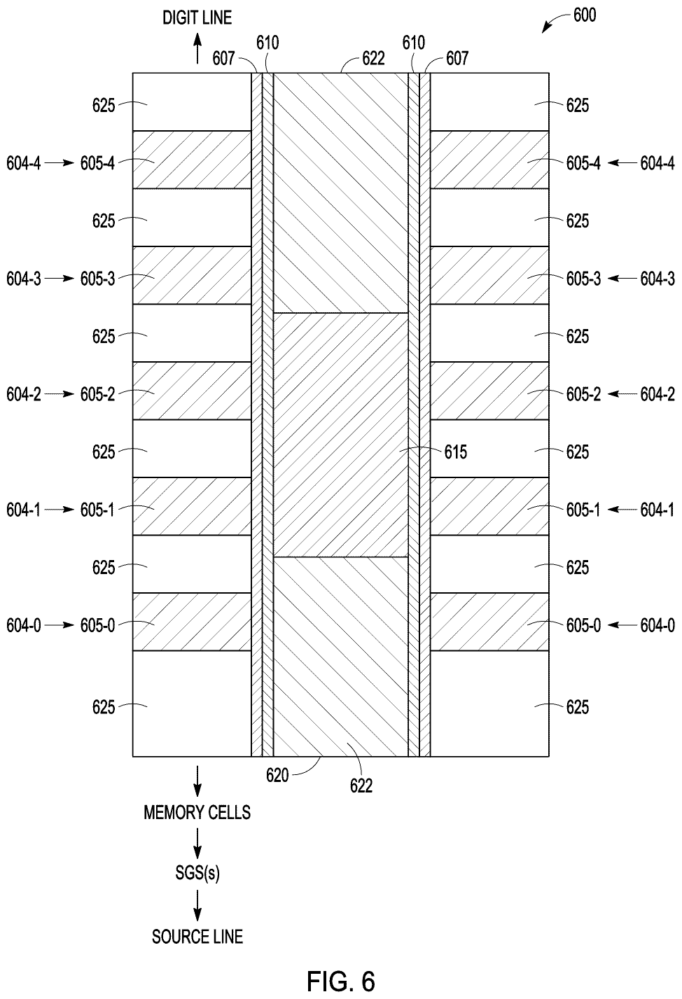

FIG. 6 illustrates an arrangement 600 in a memory device having SGD transistors 604-0, 604-1, 604-2, 604-3, and 604-4 vertically positioned above and coupled to memory cells, with the memory cells arranged above one or more SGS transistors coupled to a source line of the memory device. SGD transistors 604-0, 604-1, 604-2, 604-3, and 604-4, arranged in a vertical stack, can be coupled to a digit line above SGD transistors 604-0, 604-1, 604-2, 604-3, and 604-4. A channel structure 610 can be arranged vertically in the stack of SGD transistors 604-0, 604-1, 604-2, 604-3, and 604-4 such that channel structure 610 provides a transistor channel for SGD transistors 604-0, 604-1, 604-2, 604-3, and 604-4. Isolation regions 625 separate each of SGD transistors 604-0, 604-1, 604-2, 604-3, and 604-4 from directly adjacent ones of SGD transistors 604-0, 604-1, 604-2, 604-3, and 604-4. Channel structure 610 can be arranged to run continuously in the vertical stack of SGD transistors 604-0, 604-1, 604-2, 604-3, and 604-4. A gate dielectric material 607 provides a gate dielectric for each of SGD transistors 604-0, 604-1, 604-2, 604-3, and 604-4. Gate dielectric material 607 can be arranged to run continuously in the vertical stack of SGD transistors 604-0, 604-1, 604-2, 604-3, and 604-4, vertically contacting the isolation regions 625. Alternatively, gate dielectric material 607 can be segmented positioned vertically between isolation regions 625. SGD transistors 604-0, 604-1, 604-2, 604-3, and 604-4 can include gates 605-0, 605-1, 605-2, 605-3, and 605-4, respectively, separated by gate dielectric material 607 from channel structure 610. SGD transistors 604-0, 604-1, 604-2, 604-3, and 604-4 can be structured to provide a configuration of a sequence of Vts in the stack of SGD transistors 604-0, 604-1, 604-2, 604-3, and 604-4. The configuration can be a sequence of medium, high, and low Vts.

Each gate of SGD transistors 604-0, 604-1, 604-2, 604-3, and 604-4 can be coupled to a SGD select line assigned to each of SGD transistors 604-0, 604-1, 604-2, 604-3, and 604-4. Selected ones of the SGD select lines can be coupled together to provide the same voltage to the gates of the corresponding selected ones of the SGD transistors. Alternatively, none of the gates of the SGD transistors are coupled together. Though FIG. 6 shows arrangement 600 having five SGD transistors, arrangement 600 can have more or fewer than five SGD transistors.

Arrangement 600 can include SGD transistors 604-0, 604-1, 604-2, 604-3, and 604-4 formed around a dielectric fill 620. In the fabrication process, dielectric fill 620 can be formed after forming the SGD transistors. Dielectric fill 620 can include a dielectric liner 615 and a dielectric region 622. Dielectric liner 615 can be a high-k dielectric liner and dielectric region 622 can be a non-high-k dielectric region. Dielectric liner 615 can extend from above SGD transistor 604-2, which is a middle SGD transistor of the multiple SGD transistors of arrangement 600, to below SGD transistor 604-1, which is a middle SGD transistor above the bottommost transistor SGD transistor 604-0 of the stack. Dielectric liner 615 can be formed having a thickness that fills dielectric fill 620 in the horizontal direction. Dielectric region 622 can be formed on and contacting dielectric liner 615 and below dielectric liner 615 while contacting dielectric liner 615. The Vts of SGD transistor 604-1 and SGD transistor 604-2 are tuned to a high Vt. The Vts of the SGD transistor 604-3 and the SGD transistor 604-4 can be tuned to a medium Vt by doping channel structure 610 adjacent SGD transistors 604-3 and 604-4 or other tuning mechanism that does not use a high-k dielectric liner such as dielectric liner 615. The Vt of the SGD transistor 604-0 can be tuned to a low Vt by doping channel structure 610 adjacent SGD transistor 604-0 or other tuning mechanism that does not use a high-k dielectric liner such as dielectric liner 615. The doping can be performed prior to forming dielectric liner 615. The various Vt-adjusting doping can include, but is not limited to, boron doping.

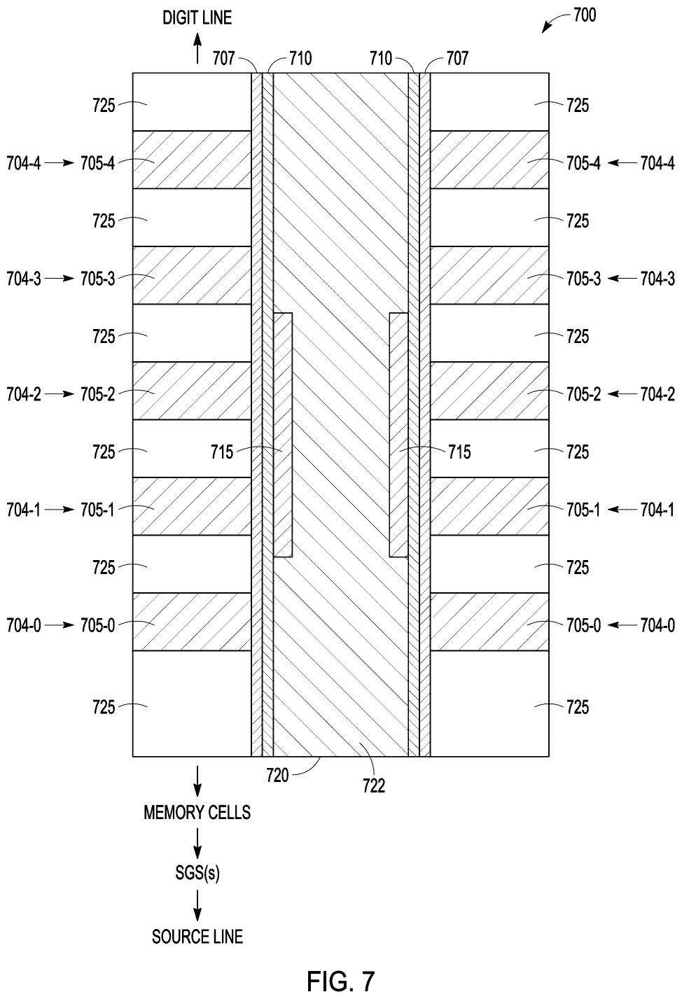

FIG. 7 illustrates an arrangement 700 in a memory device having SGD transistors 704-0, 704-1, 704-2, 704-3, and 704-4 vertically positioned above and coupled to memory cells, with the memory cells arranged above one or more SGS transistors coupled to a source line of the memory device. SGD transistors 704-0, 704-1, 704-2, 704-3, and 704-4, arranged in a vertical stack, can be coupled to a digit line above SGD transistors 704-0, 704-1, 704-2, 704-3, and 704-4. A channel structure 710 can be arranged vertically in the stack of SGD transistors 704-0, 704-1, 704-2, 704-3, and 704-4 such that channel structure 710 provides a transistor channel for SGD transistors 704-0, 704-1, 704-2, 704-3, and 704-4. Isolation regions 725 separate each of SGD transistors 704-0, 704-1, 704-2, 704-3, and 704-4 from directly adjacent ones of SGD transistors 704-0, 704-1, 704-2, 704-3, and 704-4. Channel structure 710 can be arranged to run continuously in the vertical stack of SGD transistors 704-0, 704-1, 704-2, 704-3, and 704-4. A gate dielectric material 707 provides a gate dielectric for each of SGD transistors 704-0, 704-1, 704-2, 704-3, and 704-4. Gate dielectric material 707 can be arranged to run continuously in the vertical stack of SGD transistors 704-0, 704-1, 704-2, 704-3, and 704-4, vertically contacting the isolation regions 725. Alternatively, gate dielectric material 707 can be segmented positioned vertically between isolation regions 725. SGD transistors 704-0, 704-1, 704-2, 704-3, and 704-4 can include gates 705-0, 705-1, 705-2, 705-3, and 705-4, respectively, separated by gate dielectric material 707 from channel structure 710. SGD transistors 704-0, 704-1, 704-2, 704-3, and 704-4 can be structured to provide a configuration of a sequence of Vts in the stack of SGD transistors 704-0, 704-1, 704-2, 704-3, and 704-4. The configuration can be a sequence of medium, high, and low Vts.

Each gate of SGD transistors 704-0, 704-1, 704-2, 704-3, and 704-4 can be coupled to a SGD select line assigned to each of SGD transistors 704-0, 704-1, 704-2, 704-3, and 704-4. Selected ones of the SGD select lines can be coupled together to provide the same voltage to the gates of the corresponding selected ones of the SGD transistors. Alternatively, none of the gates of the SGD transistors are coupled together. Though FIG. 7 shows arrangement 700 having five SGD transistors, arrangement 700 can have more or fewer than five SGD transistors.

Arrangement 700 can include SGD transistors 704-0, 704-1, 704-2, 704-3, and 704-4 formed around a dielectric fill 720. In the fabrication process, dielectric fill 720 can be formed after forming the SGD transistors. Dielectric fill 720 can include a dielectric liner 715 and a dielectric region 722. Dielectric liner 715 can be a high-k dielectric liner and dielectric region 722 can be a non-high-k dielectric region. Dielectric liner 715 can extend from above SGD transistor 704-2, which is a middle SGD transistor of the multiple SGD transistors of arrangement 700, to below SGD transistor 704-1, which is a middle SGD transistor above the bottommost transistor SGD transistor 704-0 of the stack. Dielectric liner 715 can be formed having a thin thickness that fills dielectric fill 720 in the horizontal direction. Dielectric region 722 can be formed on and contacting dielectric liner 715 and below dielectric liner 715 while contacting dielectric liner 715. Dielectric region 722 can also be formed separated from SGD transistors 704-1 and 704-2 by dielectric liner 715. The Vts of SGD transistor 704-1 and SGD transistor 704-2 are tuned to a high Vt. The Vts of the SGD transistor 704-3 and the SGD transistor 704-4 can be tuned to a medium Vt by doping channel structure 710 adjacent SGD transistors 704-3 and 704-4 or other tuning mechanism that does not use a high-k dielectric liner such as dielectric liner 715. The Vt of the SGD transistor 704-0 can be tuned to a low Vt by doping channel structure 710 adjacent SGD transistor 704-0 or other tuning mechanism that does not use a high-k dielectric liner such as dielectric liner 715. The doping can be performed prior to forming dielectric liner 715. The various Vt-adjusting doping can include, but is not limited to, boron doping.

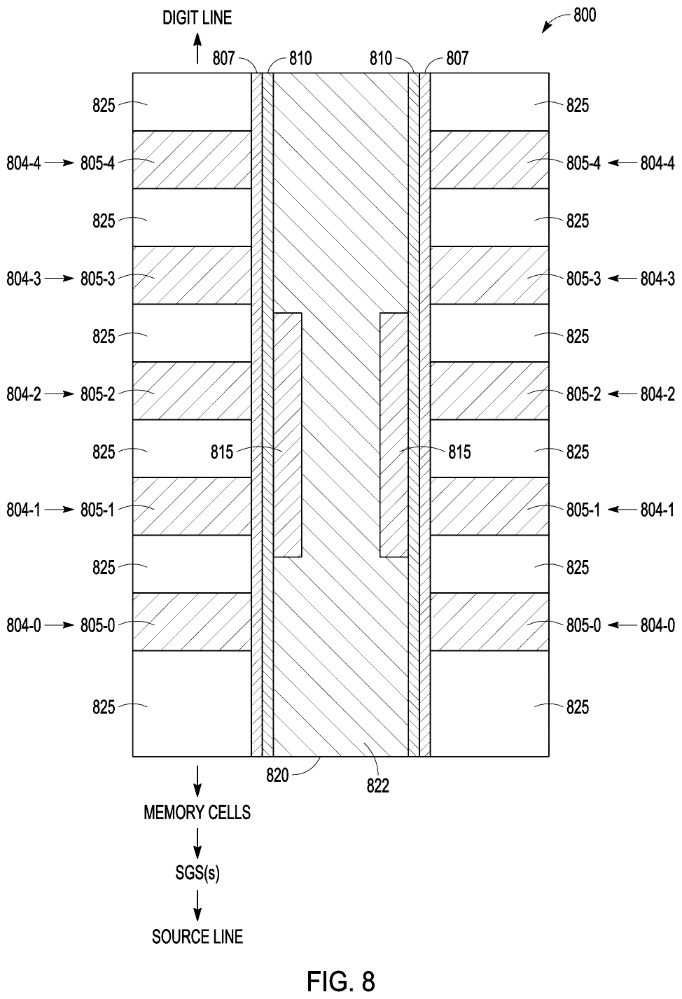

FIG. 8 illustrates an arrangement 800 in a memory device having SGD transistors 804-0, 804-1, 804-2, 804-3, and 804-4 vertically positioned above and coupled to memory cells, with the memory cells arranged above one or more SGS transistors coupled to a source line of the memory device. SGD transistors 804-0, 804-1, 804-2, 804-3, and 804-4, arranged in a vertical stack, can be coupled to a digit line above SGD transistors 804-0, 804-1, 804-2, 804-3, and 804-4. A channel structure 810 can be arranged vertically in the stack of SGD transistors 804-0, 804-1, 804-2, 804-3, and 804-4 such that channel structure 810 provides a transistor channel for SGD transistors 804-0, 804-1, 804-2, 804-3, and 804-4. Isolation regions 825 separate each of SGD transistors 804-0, 804-1, 804-2, 804-3, and 804-4 from directly adjacent ones of SGD transistors 804-0, 804-1, 804-2, 804-3, and 804-4. Channel structure 810 can be arranged to run continuously in the vertical stack of SGD transistors 804-0, 804-1, 804-2, 804-3, and 804-4. A gate dielectric material 807 provides a gate dielectric for each of SGD transistors 804-0, 804-1, 804-2, 804-3, and 804-4. Gate dielectric material 807 can be arranged to run continuously in the vertical stack of SGD transistors 804-0, 804-1, 804-2, 804-3, and 804-4, vertically contacting the isolation regions 825. Alternatively, gate dielectric material 807 can be segmented positioned vertically between isolation regions 825. SGD transistors 804-0, 804-1, 804-2, 804-3, and 804-4 can include gates 805-0, 805-1, 805-2, 805-3, and 805-4, respectively, separated by gate dielectric material 807 from channel structure 810. SGD transistors 804-0, 804-1, 804-2, 804-3, and 804-4 can be structured to provide a configuration of a sequence of Vts in the stack of SGD transistors 804-0, 804-1, 804-2, 804-3, and 804-4. The configuration can be a sequence of medium, high, and low Vts.

Each gate of SGD transistors 804-0, 804-1, 804-2, 804-3, and 804-4 can be coupled to a SGD select line assigned to each of SGD transistors 804-0, 804-1, 804-2, 804-3, and 804-4. Selected ones of the SGD select lines can be coupled together to provide the same voltage to the gates of the corresponding selected ones of the SGD transistors. Alternatively, none of the gates of the SGD transistors are coupled together. Though FIG. 8 shows arrangement 800 having five SGD transistors, arrangement 800 can have more or fewer than five SGD transistors.

Arrangement 800 can include SGD transistors 804-0, 804-1, 804-2, 804-3, and 804-4 formed around a dielectric fill 820. In the fabrication process, dielectric fill 820 can be formed after forming the SGD transistors. Dielectric fill 820 can include a dielectric liner 815 and a dielectric region 822. Dielectric liner 815 can be a high-k dielectric liner and dielectric region 822 can be a non-high-k dielectric region. Dielectric liner 815 can extend from above SGD transistor 804-2, which is a middle SGD transistor of the multiple SGD transistors of arrangement 800, to below SGD transistor 804-1, which is a middle SGD transistor above the bottommost transistor SGD transistor 804-0 of the stack. Dielectric liner 815 can be formed having a thin thickness that fills dielectric fill 820 in the horizontal direction. Dielectric region 822 can be formed on and contacting dielectric liner 815 and below dielectric liner 815 while contacting dielectric liner 815. Dielectric region 822 can also be formed separated from SGD transistors 804-1 and 804-2 by dielectric liner 815. The Vts of SGD transistor 804-1 and SGD transistor 804-2 are tuned to a high Vt. The Vts of the SGD transistors 804-3 and 804-4 can be tuned to a medium Vt by doping channel structure 810 adjacent SGD transistors 804-3 and 804-4 or other tuning mechanism that does not use a high-k dielectric liner such as dielectric liner 815. The Vt of the SGD transistor 804-0 can be tuned to a low Vt by doping channel structure 810 adjacent SGD transistor 804-0 or other tuning mechanism that does not use a high-k dielectric liner such as dielectric liner 815. The doping can be performed prior to forming dielectric liner 815. The various Vt-adjusting doping can include, but is not limited to, boron doping.

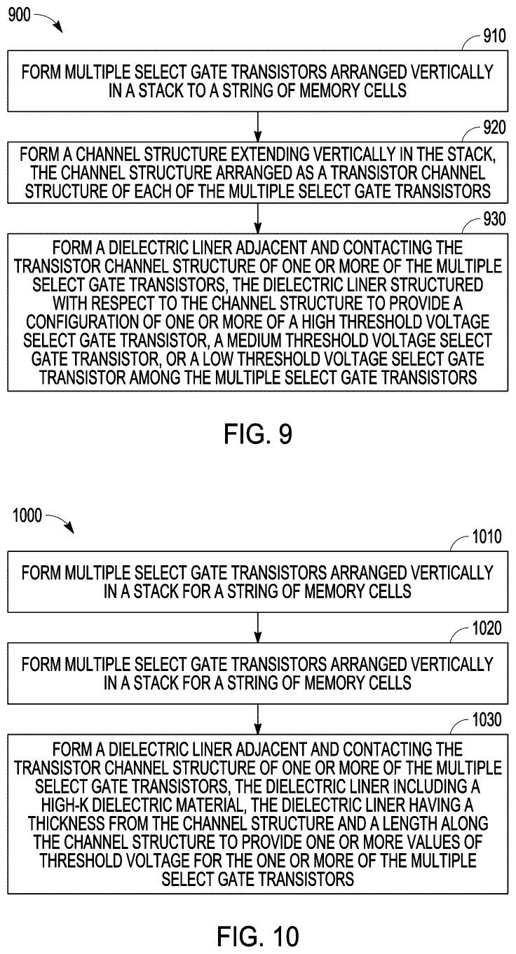

FIG. 9 is a flow diagram of an embodiment of features of a method 900 of forming a memory device having one or more select gate transistors in which threshold voltage is tuned. At 910, multiple select gate transistors are formed arranged vertically in a stack for a string of memory cells of the memory device. At 920, a channel structure is formed extending vertically in the stack, where the channel structure is arranged as a transistor channel structure of each of the multiple select gate transistors. At 930, a dielectric liner is formed adjacent and contacting the transistor channel structure of one or more of the multiple select gate transistors, where the dielectric liner is structured with respect to the channel structure to provide a configuration of one or more of a high threshold voltage select gate transistor, a medium threshold voltage select gate transistor, or a low threshold voltage select gate transistor among the multiple select gate transistors. The dielectric liner can be at least a portion of a dielectric fill around which the channel structure is formed. The dielectric liner can include a high-k dielectric material, where the dielectric liner has a thickness extending from the channel structure and a length along the channel structure.

Variations of method 900 or methods similar to method 900 can include a number of different embodiments that may be combined depending on the application of such methods or the architecture or process flow of an integrated circuit for which such methods are implemented. Such methods can include forming the dielectric liner adjacent each of the select gate transistors of the multiple select gate transistors, that is, the dielectric line can be formed adjacent and contacting all of the multiple select gate transistors. In other arrangements, the dielectric line can be formed adjacent and contacting a selected set of the multiple select gate transistors to achieve a tuning of the multiple select gate transistors for specific sequence of threshold voltages for the multiple select gate transistors.

Variations of method 900 or methods similar to the method 900 can include forming the multiple select gate transistors having a memory cell structure. Alternatively, the multiple select gate transistors can be formed as MOSFET transistors. The channel structure can be structured around a dielectric fill, where the dielectric fill contains the dielectric liner and a dielectric region below a bottommost select gate transistor of the multiple select gate transistors, where the dielectric region can be a non-high-k dielectric. An example of the non-high-k dielectric that can be formed can be a silicon oxide.

FIG. 10 is a flow diagram of an embodiment of features of a method 1000 of forming a memory device having multiple select gate transistors that can be formed with a selected sequence of threshold voltages. At 1010, multiple select gate transistors are formed arranged vertically in a stack for a string of memory cells. At 1020, a channel structure is formed extending vertically in the stack, where the channel structure is arranged as a transistor channel structure of each of the multiple select gate transistors. At 1030, a dielectric liner is formed adjacent and contacting the transistor channel structure of one or more of the multiple select gate transistors, where the dielectric liner includes a high-k dielectric material and has a thickness from the channel structure and a length along the channel structure to provide one or more values of threshold voltage for the multiple select gate transistors.

Variations of method 1000 or methods similar to method 1000 can include a number of different embodiments that may be combined depending on the application of such methods or the architecture or process flow of an integrated circuit for which such methods are implemented. Such variations can include, but is not limited to, forming the high-k dielectric material by forming aluminum oxide. Other high-k dielectric materials can be used.

Variations of method 1000 can include variation of the location of the dielectric liner. Variations can include forming the dielectric liner extending from above a topmost select gate transistor of the multiple select gate transistors to below one or more select gate transistors in a sequence of select gate transistors arranged vertically directly from the topmost select gate transistor, with another one or more select gate transistor of the multiple select gate transistors below the sequence. A gate of the topmost select gate transistor and gates of the one or more select gate transistors in the sequence can be electrically coupled together. The channel structure can be structured around a dielectric fill, where the dielectric fill contains the dielectric liner, and the dielectric liner has a thickness in a horizontal direction equal to or less than a thirteenth of a radius of the dielectric fill. Other thicknesses can be used. In another configuration, the channel structure can be structured around a dielectric fill, where the dielectric fill contains the dielectric liner, and the dielectric liner has a thickness in a horizontal direction greater than a thirteenth of a radius of the dielectric fill and less than the radius of the dielectric fill. Other thickness ranges can be used. In another configuration, the channel structure can be structured around a dielectric fill, where the dielectric fill contains the dielectric liner without other material in the dielectric fill extending from adjacent the topmost select gate transistor of the multiple select gate transistors to below the sequence of select gate transistors.

Variations of method 1000 can include forming the dielectric liner extending from above a topmost select gate transistor of the multiple select gate transistors to below a bottommost select gate transistor of the multiple select gate transistors. The channel structure can be structured around a dielectric fill, with the dielectric fill containing the dielectric liner without other material in the dielectric fill above a non-high-k dielectric region. In another configuration, the channel structure can be structured around a dielectric fill, where the dielectric fill contains the dielectric liner, and the dielectric liner has a thickness in a horizontal direction equal to or less than a thirteenth of a radius of the dielectric fill. Other thicknesses can be used.

Variations of method 1000 can include forming the dielectric liner extending from below a select gate transistor of the multiple select gate transistors in a vertical direction down to above another select gate transistor of the multiple select gate transistors. The channel structure can be structured around a dielectric fill, where the dielectric fill contains the dielectric liner, and the dielectric liner has a thickness in a horizontal direction equal to or less than a thirteenth of a radius of the dielectric fill. Other thin thicknesses can be used. In another configuration, the channel structure can be structured around a dielectric fill, where the dielectric fill contains the dielectric liner, and the dielectric liner has a thickness in a horizontal direction greater than a thirteenth of a radius of the dielectric fill and less than the radius of the dielectric fill. Other thickness ranges can be used. In another configuration, the channel structure can be structured around a dielectric fill, where the dielectric fill contains the dielectric liner, a first dielectric region on and contacting the dielectric liner, and a second dielectric region on which the dielectric liner is located. The dielectric liner can have a radius equal to that of the dielectric fill, where the first dielectric region and the second dielectric region are non-high-k dielectrics.

Various deposition techniques for forming components of arrangments 100-800 of FIGS. 1-8 and the methods associated with FIGS. 9 and 10 can be used that are typical for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing. Selective etching is a process in which one or more materials are removed from a structure, while one or more other materials remain in the structure with no or little removal. Selective etching can depend on the material to be etched, the material not to be etched, the etchant employed, and the method for etching. Etching procedures can include, but are not limited to, wet etching, dry etching, and atomic layer etching deposition, among others, where each of these basic methods include a number of different etching procedures.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and Internet-connected appliances or devices (e.g., Internet-of-Things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, an SSD, an MMC, or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc.

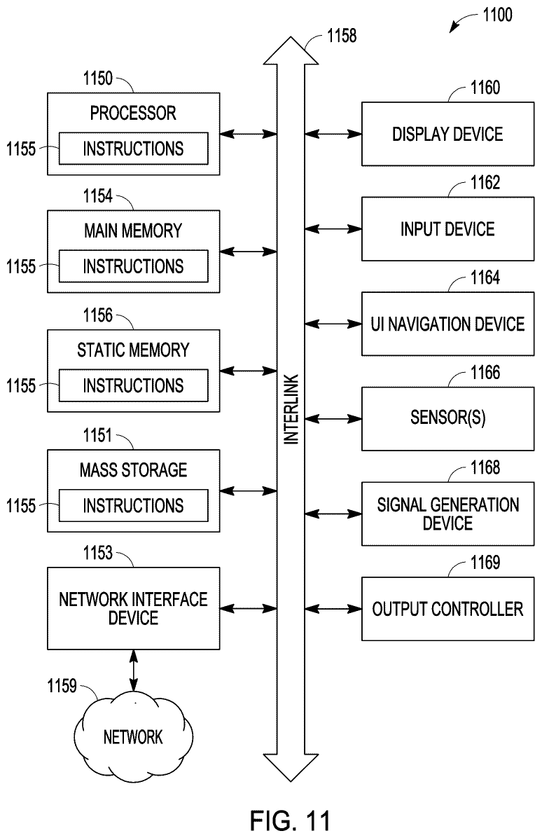

FIG. 11 illustrates a block diagram of an example machine 1100 having one or more memory devices structured with a dielectric liner adjacent and contacting channel structures of SGD transistors to a string of memory cells, where the dielectric liner was implemented to tune the Vts of the one or more SGD transistors. The machine 1100, having one or more such memory devices, may operate as a standalone machine or may be connected, for example networked, to other machines.

In a networked deployment, the machine 1100 may operate in the capacity of a server machine, a client machine, or both in server-client network environments. In an example, the machine 1100 may act as a peer machine in peer-to-peer (P2P) (or other distributed) network environment. The machine 1100 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The example machine 1100 can be arranged to operate with one or more memory devices having liners for select gate threshold voltage tuning of one or more SGD transistors as taught herein.

The machine (e.g., computer system) 1100 may include a hardware processor 1150 (e.g., a CPU, a GPU, a hardware processor core, or any combination thereof), a main memory 1154, and a static memory 1156, some or all of which may communicate with each other via an interlink (e.g., bus) 1158. The machine 1100 may further include a display device 1160, an alphanumeric input device 1162 (e.g., a keyboard), and a user interface (UI) navigation device 1164 (e.g., a mouse). In an example, the display device 1160, input device 1162, and UI navigation device 1164 may be a touch screen display. The machine 1100 may additionally include a mass storage device (e.g., drive unit) 1151, a signal generation device 1168 (e.g., a speaker), a network interface device 1153, and one or more sensors 1166, such as a global positioning system (GPS) sensor, compass, accelerometer, or other sensor. The machine 1100 may include an output controller 1169, such as a serial (e.g., USB, parallel, or other wired or wireless (e.g., infrared (IR), near field communication (NFC), etc.) connection to communicate or control one or more peripheral devices (e.g., a printer, card reader, etc.).

The machine 1100 may include machine-readable media on which is stored one or more sets of data structures or instructions 1155 (e.g., software) embodying or utilized by the machine 1100 to perform any one or more of the techniques or functions for which the machine 1100 is designed. The machine-readable media can include main memory 1154, static memory 1156, or mass storage device 1151. The instructions 1155 may reside, completely or at least partially, within main memory 1154, within static memory 1156, within the mass storage device 1151, or within the hardware processor 1150 during execution thereof by the machine 1100.

While each of the machine-readable media is illustrated as a single medium, the term “machine-readable medium” may include a single medium or multiple media (e.g., a centralized or distributed database, or associated caches and servers) configured to store the one or more instructions 1155. The term “machine-readable medium” may include any medium that is capable of storing, encoding, or holding instructions for execution by the machine 1100 and that cause the machine 1100 to perform any one or more of the techniques to which the machine 1100 is designed, or that is capable of storing, encoding, or holding data structures used by or associated with such instructions. Non-limiting machine-readable medium examples may include solid-state memories, optical and magnetic media, or other tangible structures. Examples of machine-readable media can include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

The instructions 1155 (e.g., software, programs, an operating system (OS), etc.) or other data, stored on the mass storage device 1151, can be accessed by the main memory 1154 for use by the processor 1150. The main memory 1154 (e.g., DRAM) is typically fast, but volatile, and thus a different type of storage than the mass storage device 1151 (e.g., an SSD), which is suitable for long-term storage, including while in an “off” condition. The instructions 1155 or data in use by a user or the machine 1100 are typically loaded in the main memory 1154 for use by the processor 1150. When the main memory 1154 is full, virtual space from the mass storage device 1151 can be allocated to supplement the main memory 1154; however, because the mass storage device 1151 is typically slower than the main memory 1154, and write speeds are typically at least twice as slow as read speeds, use of virtual memory can greatly reduce user experience due to storage device latency (in contrast to the main memory 1154, e.g., DRAM). Further, use of the mass storage device 1151 for virtual memory can greatly reduce the usable lifespan of the mass storage device 1151.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA-based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

The instructions 1155 may further be transmitted or received over a communications network 1159 using a transmission medium via the network interface device 1153 utilizing any one of a number of transfer protocols (e.g., frame relay, Internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 1153 may include one or more physical jacks (e.g., Ethernet, coaxial, or phone jacks) or one or more antennas to connect to the communications network 1159. In an example, the network interface device 1153 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by the machine 1100, and includes instrumentalities to propagate digital or analog communications signals to facilitate communication of such instructions, which instructions may be implemented by software.

The following are example embodiments of devices and methods, in accordance with the teachings herein.

An example memory device 1 can comprise multiple select gate transistors arranged vertically in a stack to a string of memory cells; a channel structure extending vertically in the stack, the channel structure arranged as a transistor channel structure of each of the multiple select gate transistors; and a dielectric liner adjacent and contacting the transistor channel structure of one or more of the multiple select gate transistors, the dielectric liner structured with respect to the channel structure to provide a configuration of one or more of a high threshold voltage select gate transistor, a medium threshold voltage select gate transistor, or a low threshold voltage select gate transistor among the multiple select gate transistors.

An example memory device 2 can include features of example memory device 1 and can include the dielectric liner including a high-k dielectric material.

An example memory device 3 can include features of any of the preceding example memory devices and can include the channel structure being structured around a dielectric fill, the dielectric fill containing the dielectric liner and a dielectric region below a bottommost select gate transistor of the multiple select gate transistors, the dielectric region being a non-high-k dielectric.

In an example memory device 4, any of the memory devices of example memory devices 1 to 3 may include components incorporated into an electronic apparatus further comprising one or more host processors and a communication bus extending between the one or more host processors and the memory device.

In an example memory device 5, any of the memory devices of example memory devices 1 to 4 may be modified to include any structure presented in another of example memory device 1 to 4.

In an example memory device 6, any apparatus associated with the memory devices of example memory devices 1 to 5 may further include a machine-readable storage device configured to store instructions as a physical state, wherein the instructions may be used to perform one or more operations of the apparatus.

In an example memory device 7, any of the memory devices of example memory devices 1 to 6 may be operated in accordance with any of the below example methods 1 to 17.

An example memory device 8 can comprise: multiple select gate transistors arranged vertically in a stack to a string of memory cells; a channel structure extending vertically in the stack, the channel structure arranged as a transistor channel structure of each of the multiple select gate transistors; and a dielectric liner adjacent and contacting the transistor channel structure of one or more of the multiple select gate transistors, the dielectric liner including a high-k dielectric material, the dielectric liner having a thickness from the channel structure and a length along the channel structure to provide one or more values of threshold voltage for the multiple select gate transistors.

An example memory device 9 can include features of example memory device 8 and can include the high-k dielectric material including aluminum oxide.

An example memory device 10 can include features of any of the preceding example memory devices 8 to 9 and can include the dielectric liner extending from above a topmost select gate transistor of the multiple select gate transistors to below one or more select gate transistors in a sequence of select gate transistors arranged vertically directly from the topmost select gate transistor, with another one or more select gate transistor of the multiple select gate transistors below the sequence.

An example memory device 11 can include features of any of the preceding example memory devices 8 to 10 and can include a gate of the topmost select gate transistor and gates of the one or more select gate transistors in the sequence being electrically coupled together.

An example memory device 12 can include features of example memory device 10 and any of the preceding example memory devices 8 to 9 or 11 and can include the channel structure being structured around a dielectric fill, the dielectric fill containing the dielectric liner, the dielectric liner having a thickness in a horizontal direction equal to or less than one-thirteenth of a radius of the dielectric fill.

An example memory device 13 can include features of example memory device 10 and any of the preceding example memory devices 8 to 9 or 11 to 12 and can include the channel structure being structured around a dielectric fill, the dielectric fill containing the dielectric liner, the dielectric liner having a thickness in a horizontal direction greater than one-thirteenth of a radius of the dielectric fill and less than the radius of the dielectric fill.

An example memory device 14 can include features of example memory device 10 and any of the preceding example memory devices 8 to 9 or 11 to 13 and can include the channel structure being structured around a dielectric fill, the dielectric fill containing the dielectric liner without other material in the dielectric fill extending from adjacent the topmost select gate transistor of the multiple select gate transistors to below the sequence of select gate transistors.

An example memory device 15 can include features of any of the preceding example memory devices 8 to 14 and can include the dielectric liner extending from above a topmost select gate transistor of the multiple select gate transistors to below a bottommost select gate transistor of the multiple select gate transistors.

An example memory device 16 can include features of example memory device 15 and any of the preceding example memory devices 8 to 14 and can include the channel structure being structured around a dielectric fill, the dielectric fill containing the dielectric liner without other material in the dielectric fill above a non-high-k dielectric region.

An example memory device 17 can include features of example memory device 15 and any of the preceding example memory devices 8 to 14 or example memory device 16 and can include the channel structure being structured around a dielectric fill, the dielectric fill containing the dielectric liner, the dielectric liner having a thickness in a horizontal direction equal to or less than one-thirteenth of a radius of the dielectric fill.

An example memory device 18 can include features of any of the preceding example memory devices 8 to 17 and can include the dielectric liner extending from below a select gate transistor of the multiple select gate transistors in a vertical direction down to above another select gate transistor of the multiple select gate transistors.

An example memory device 19 can include features of example memory device 18 and any of the preceding example memory devices 8 to 17 and can include the channel structure being structured around a dielectric fill, the dielectric fill containing the dielectric liner, the dielectric liner having a thickness in a horizontal direction equal to or less than one-thirteenth of a radius of the dielectric fill.

An example memory device 20 can include features of example memory device 19 and any of the preceding example memory devices 8 to 18 and can include the channel structure being structured around a dielectric fill, the dielectric fill containing the dielectric liner, the dielectric liner having a thickness in a horizontal direction greater than one-thirteenth of a radius of the dielectric fill and less than the radius of the dielectric fill.

An example memory device 21 can include features of example memory device 20 and any of the preceding example memory devices 8 to 19 and can include the channel structure being structured around a dielectric fill, the dielectric fill containing the dielectric liner, a first dielectric region on and contacting the dielectric liner, and a second dielectric region on which the dielectric liner is located, the dielectric liner having a radius equal to that of the dielectric fill, the first dielectric region and the second dielectric region being non-high-k dielectrics.

In an example memory device 22, any of the memory devices of example memory devices 8 to 21 may include memory devices incorporated into an electronic apparatus further comprising a host processor or memory controller and a communication bus extending between the host processor/memory controller and the memory device.

In an example memory device 23, any of the memory devices of example memory devices 8 to 22 may be modified to include any structure presented in another of example memory device 1 to 7.

In an example memory device 24, any apparatus associated with the memory devices of example memory devices 8 to 23 may further include a machine-readable storage device configured to store instructions as a physical state, wherein the instructions may be used to perform one or more operations of the apparatus.

In an example memory device 25, any of the memory devices of example memory devices 8 to 24 may be operated in accordance with any of the below example methods 1 to 17.

An example method 1 can comprise forming multiple select gate transistors arranged vertically in a stack to a string of memory cells; forming a channel structure extending vertically in the stack, the channel structure arranged as a transistor channel structure of each of the multiple select gate transistors; and forming a dielectric liner adjacent and contacting the transistor channel structure of one or more of the multiple select gate transistors, the dielectric liner structured with respect to the channel structure to provide a configuration of one or more of a high threshold voltage select gate transistor, a medium threshold voltage select gate transistor, or a low threshold voltage select gate transistor among the multiple select gate transistors.

An example method 2 can include features of example method 1 and can include forming the dielectric liner adjacent each of the select gate transistors of the multiple select gate transistors.

An example method 3 can include features of any of the preceding example methods and can include forming the multiple select gate transistors having a memory cell structure.

In an example method 4, any of the example methods 1 to 3 may be performed in an electronic apparatus further comprising a host processor and a communication bus extending between the host processor and the memory system.

In an example method 5, any of the example methods 1 to 4 may be modified to include operations set forth in any other of example methods 1 to 4.

In an example method 6, any of the example methods 1 to 5 may be implemented at least in part through use of instructions stored as a physical state in one or more machine-readable storage devices.

An example method 7 can include features of any of the preceding example methods 1 to 6 and can include performing functions associated with any features of example memory devices 1 to 25.

An example method 8 can comprise: forming multiple select gate transistors arranged vertically in a stack to a string of memory cells; forming a channel structure extending vertically in the stack, the channel structure arranged as a transistor channel structure of each of the multiple select gate transistors; and forming a dielectric liner adjacent and contacting the transistor channel structure of one or more of the multiple select gate transistors, the dielectric liner including a high-k dielectric material, the dielectric liner having a thickness from the channel structure and a length along the channel structure to provide one or more values of threshold voltage for the multiple select gate transistors.

An example method 9 can include features of example method 8 and can include forming the high-k dielectric material to include forming aluminum oxide.

An example method 10 can include features of any of the preceding example methods 8 to 9 and can include forming the dielectric liner extending from above a topmost select gate transistor of the multiple select gate transistors to below one or more select gate transistors in a sequence of select gate transistors arranged vertically directly from the topmost select gate transistor, with another one or more select gate transistor of the multiple select gate transistors below the sequence.

An example method 11 can include features of example method 10 and any of the preceding example methods 8 to 9 and can include electrically coupling together a gate of the topmost select gate transistor and gates of the one or more select gate transistors in the sequence.

An example method 12 can include features of example method 10 and any of the preceding example methods 8 to 9 or 11 and can include structuring the channel structure around a dielectric fill, the dielectric fill containing the dielectric liner, the dielectric liner having a thickness in a horizontal direction equal to or less than one-thirteenth of a radius of the dielectric fill.

An example method 13 can include features of example method 10 and any of the preceding example methods 8 to 9 or 11 to 12 and can include structuring the channel structure around a dielectric fill, the dielectric fill containing the dielectric liner, the dielectric liner having a thickness in a horizontal direction greater than one-thirteenth of a radius of the dielectric fill and less than the radius of the dielectric fill.

An example method 14 can include features of example method 10 and any of the preceding example methods 8 to 9 or 11 to 13 and can include structuring the channel structure around a dielectric fill, the dielectric fill containing the dielectric liner without other material in the dielectric fill extending from adjacent the topmost select gate transistor of the multiple select gate transistors to below the sequence of select gate transistors.

An example method 15 can include features of any of the preceding example methods and 8 to 14 can include forming the dielectric liner extending from above a topmost select gate transistor of the multiple select gate transistors to below a bottommost select gate transistor of the multiple select gate transistors.

An example method 16 can include features of example method 15 and any of the preceding example methods 8 to 14 and can include structuring the channel structure around a dielectric fill, the dielectric fill containing the dielectric liner without other material in the dielectric fill above a non-high-k dielectric region.

An example method 17 can include features of example method 15 and any of the preceding example methods 8 to 14 or 16 and can include structuring the channel structure around a dielectric fill, the dielectric fill containing the dielectric liner, the dielectric liner having a thickness in a horizontal direction equal to or less than one-thirteenth of a radius of the dielectric fill.

An example method 18 can include features of any of the preceding example methods 8 to 17 and can include forming the dielectric liner extending from below a select gate transistor of the multiple select gate transistors in a vertical direction down to above another select gate transistor of the multiple select gate transistors.

An example method 19 can include features of example method 18 and any of the preceding example methods 8 to 17 and can include structuring the channel structure around a dielectric fill, the dielectric fill containing the dielectric liner, the dielectric liner having a thickness in a horizontal direction equal to or less than one-thirteenth of a radius of the dielectric fill.

An example method 20 can include features of example method 18 and any of the preceding example methods 8 to 17 or 19 and can include structuring the channel structure around a dielectric fill, the dielectric fill containing the dielectric liner, the dielectric liner having a thickness in a horizontal direction greater than one-thirteenth of a radius of the dielectric fill and less than the radius of the dielectric fill.

An example method 21 can include features of example method 18 and any of the preceding example methods 8 to 17 or 19 to 20 and can structuring the channel structure around a dielectric fill, the dielectric fill containing the dielectric liner, a first dielectric region on and contacting the dielectric liner, and a second dielectric region on which the dielectric liner is located, the dielectric liner having a radius equal to that of the dielectric fill, the first dielectric region and the second dielectric region being non-high-k dielectrics.

In an example method 22, any of the example methods 8 to 21 may be performed in an electronic apparatus further comprising a host processor and a communication bus extending between the host processor and the memory system.

In an example method 23, any of the example methods 8 to 22 may be modified to include operations set forth in any other of example methods 8 to 22.

In an example method 24, any of the example methods 8 to 23 may be implemented at least in part through use of instructions stored as a physical state in one or more machine-readable storage devices.

An example method 25 can include features of any of the preceding example methods 8 to 24 and can include performing functions associated with any features of example memory devices 1 to 25.

An example machine-readable storage device storing instructions, that when executed by one or more processors, cause a machine to perform operations, can comprise instructions to perform functions associated with any features of example memory devices 1 to 25 or perform methods associated with any features of example methods 1 to 25.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. The above description is intended to be illustrative, and not restrictive, and the phraseology or terminology employed herein is for the purpose of description. In addition, in the foregoing Detailed Description, it can be seen that various features are grouped together in a single embodiment for the purpose of streamlining the disclosure. Combinations of the above embodiments and other embodiments will be apparent to those of skill in the art upon studying the above description.

What is claimed is:

1. A memory device comprising:
multiple select gate transistors arranged vertically in a stack to a string of memory cells;
a channel structure extending vertically in the stack, the channel structure arranged as a transistor channel structure of each of the multiple select gate transistors; and
a dielectric liner adjacent and contacting the transistor channel structure of one or more of the multiple select gate transistors, the dielectric liner structured with respect to the channel structure to provide a configuration of one or more of a high threshold voltage select gate transistor, a medium threshold voltage select gate transistor, or a low threshold voltage select gate transistor among the multiple select gate transistors.

2. The memory device of claim 1, wherein the dielectric liner includes a high-k dielectric material.

3. The memory device of claim 1, wherein the channel structure is structured around a dielectric fill, the dielectric fill containing the dielectric liner and a dielectric region below a bottommost select gate transistor of the multiple select gate transistors, the dielectric region being a non-high-k dielectric.

4. A memory device comprising:
multiple select gate transistors arranged vertically in a stack to a string of memory cells;
a channel structure extending vertically in the stack, the channel structure arranged as a transistor channel structure of each of the multiple select gate transistors; and
a dielectric liner adjacent and contacting the transistor channel structure of one or more of the multiple select gate transistors, the dielectric liner including a high-k dielectric material, the dielectric liner having a thickness from the channel structure and a length along the channel structure to provide one or more values of threshold voltage for the multiple select gate transistors.

5. The memory device of claim 4, wherein the high-k dielectric material includes aluminum oxide.

6. The memory device of claim 4, wherein the dielectric liner extends from above a topmost select gate transistor of the multiple select gate transistors to below one or more select gate transistors in a sequence of select gate transistors arranged vertically directly from the topmost select gate transistor, with another one or more select gate transistor of the multiple select gate transistors below the sequence.

7. The memory device of claim 6, wherein a gate of the topmost select gate transistor and gates of the one or more select gate transistors in the sequence are electrically coupled together.

8. The memory device of claim 6, wherein the channel structure is structured around a dielectric fill, the dielectric fill containing the dielectric liner, the dielectric liner having a thickness in a horizontal direction equal to or less than one-thirteenth of a radius of the dielectric fill.

9. The memory device of claim 6, wherein the channel structure is structured around a dielectric fill, the dielectric fill containing the dielectric liner, the dielectric liner having a thickness in a horizontal direction greater than one-thirteenth of a radius of the dielectric fill and less than the radius of the dielectric fill.

10. The memory device of claim 6, wherein the channel structure is structured around a dielectric fill, the dielectric fill containing the dielectric liner without other material in the dielectric fill extending from adjacent the topmost select gate transistor of the multiple select gate transistors to below the sequence of select gate transistors.

11. The memory device of claim 4, wherein the dielectric liner extends from above a topmost select gate transistor of the multiple select gate transistors to below a bottommost select gate transistor of the multiple select gate transistors.

12. The memory device of claim 11, wherein the channel structure is structured around a dielectric fill, the dielectric fill containing the dielectric liner without other material in the dielectric fill above a non-high-k dielectric region.

13. The memory device of claim 11, wherein the channel structure is structured around a dielectric fill, the dielectric fill containing the dielectric liner, the dielectric liner having a thickness in a horizontal direction equal to or less than one-thirteenth of a radius of the dielectric fill.

14. The memory device of claim 4, wherein the dielectric liner extends from below a select gate transistor of the multiple select gate transistors in a vertical direction down to above another select gate transistor of the multiple select gate transistors.

15. The memory device of claim 14, wherein the channel structure is structured around a dielectric fill, the dielectric fill containing the dielectric liner, the dielectric liner having a thickness in a horizontal direction equal to or less than one-thirteenth of a radius of the dielectric fill.

16. The memory device of claim 14, wherein the channel structure is structured around a dielectric fill, the dielectric fill containing the dielectric liner, the dielectric liner having a thickness in a horizontal direction greater than one-thirteenth of a radius of the dielectric fill and less than the radius of the dielectric fill.

17. The memory device of claim 14, wherein the channel structure is structured around a dielectric fill, the dielectric fill containing the dielectric liner, a first dielectric region on and contacting the dielectric liner, and a second dielectric region on which the dielectric liner is located, the dielectric liner having a radius equal to that of the dielectric fill, the first dielectric region and the second dielectric region being non-high-k dielectrics.

18. A method comprising:
forming multiple select gate transistors arranged vertically in a stack to a string of memory cells;
forming a channel structure extending vertically in the stack, the channel structure arranged as a transistor channel structure of each of the multiple select gate transistors; and
forming a dielectric liner adjacent and contacting the transistor channel structure of one or more of the multiple select gate transistors, the dielectric liner structured with respect to the channel structure to provide a configuration of one or more of a high threshold voltage select gate transistor, a medium threshold voltage select gate transistor, or a low threshold voltage select gate transistor among the multiple select gate transistors.

19. The method of claim 18, wherein the method includes forming the dielectric liner adjacent each of the select gate transistors of the multiple select gate transistors.

20. The method of claim 18, wherein the method includes forming the multiple select gate transistors having a memory cell structure.
